(19) United States
(12) Patent Application Publication
(10) Pub. No.: US 2018/0261594 A1
(43) Pub. Date: Sep. 13, 2018

(54) SEMICONDUCTOR DEVICE

(71) Applicant: Fuji Electric Co., Ltd., Kanagawa (JP)

(72) Inventors: Akio YAMANO, Nagano (JP); Misaki TAKAHASHI, Nagano (JP)

(73) Assignee: Fuji Electric Co., Ltd., Kanagawa (JP)

(21) Appl. No.: 15/889,626

(22) Filed: Feb. 6, 2018

(30) Foreign Application Priority Data
Mar. 10, 2017 (JP) 2017-046475

(51) Int. Cl. H01L 27/06; H01L 29/739; H01L 29/40; H01L 29/10; H01L 29/08

(52) U.S. Cl. CPC H01L 27/0664; H01L 29/7397; H01L 29/0804; H01L 29/1004; H01L 29/407

(57) ABSTRACT

A semiconductor device includes an IGBT region and a FWD region. The IGBT region includes a plurality of trench structures, p-type base regions provided between the trench structures, n⁺ emitter regions provided on the p-type base regions, an interlayer insulating film provided on the n⁺ emitter regions and containing contact holes therein, and an emitter electrode connected to the n⁺ emitter regions through the contact holes. In a portion of the IGBT region that abuts the FWD region, the interlayer insulating film covers and insulates the trench structures without having the contact holes.

### BACKGROUND OF THE INVENTION

### Technical Field

The present invention relates to a semiconductor device used in a power conversion device or the like.

### Background Art

There has been progress in the characteristic improvement of conventional 600V, 1200V, and 1700V class power semiconductor devices, such as insulated gate bipolar transistors (IGBTs), free wheeling diodes (FWDs), and the like. These types of power semiconductor devices are used in power conversion devices such as highly efficient power-saving inverters, and are indispensable for motor control.

Furthermore, in order to make the entire power conversion device (the related chip containing the IGBT) more compact, a reverse conducting IGBT (RC-IGBT) is being developed that has an IGBT and a FWD connected anti-parallel to the IGBT that are embedded and integrated in the same semiconductor chip (see Patent Document 1 below, for example).

In regard to the RC-IGBT described above, there is disclosure of a structure in which an isolation region having a prescribed width L at or above a carrier diffusion length is provided between the IGBT region and FWD region, and a structure in which a recess is provided in the isolation region (see Patent Documents 2 and 3, for example).

### RELATED ART DOCUMENTS

### Patent Documents

Patent Document 1: WO 2016/080269

Patent Document 2: Japanese Patent Application Laid-Open Publication No. H5-152574

Patent Document 3: Japanese Patent Application Laid-Open Publication No. H10-321877

### SUMMARY OF THE INVENTION

However, in a conventional RC-IGBT, the FWD region is provided adjacent to the IGBT region. During the conduction operation of the FWD in this structure (i.e., a diode conduction state in which a prescribed voltage such as 15V has been applied to the gate), the electron current is drawn toward the emitter electrode of the IGBT region adjacent to the FWD region, which results in degradation of the forward voltage Vf.

In view of the aforementioned problem, the present invention aims at making it possible, with a simple structure, to prevent characteristic degradation of Vf during FWD operation and of Irrm during the FWD reverse recovery operation in the RC-IGBT.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device, including, a semiconductor substrate of a first conductivity type serving as a drift layer, the semiconductor substrate having two defined regions of a first region where an insulated gate bipolar transistor is disposed and a second region where a diode is disposed, wherein in the first region, the semiconductor device includes: a plurality of trench structures provided in a front surface side of the semiconductor substrate; base regions of a second conductivity type disposed between the plurality of trench structures; emitter regions of the first conductivity type respectively disposed on at least some of the base regions; an interlayer insulating film covering the emitter regions and the plurality of trench structures; and an emitter electrode on the interlayer insulating film, connected to at least some of the emitter regions, and wherein the interlayer insulating film has contact holes therein connecting the at least some of the emitter regions to the emitter electrode, the interlayer insulating film not having the contact holes in a portion of the first region that is next to and abuts a boundary between the first region and the second region, and covering and insulating at least two of the trench structures that are adjacent to the boundary in the portion of the first region.

The present invention makes it possible, with a simple structure, to prevent characteristic degradation, in an RC-IGBT, of Vf during FWD operation and of Irrm during the FWD reverse recovery operation.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view showing a configuration of the RC-IGBT and a state during operation of the FWD in Embodiment 1.

FIG. 2 is a view showing a state during a reverse recovery operation of the RC-IGBT in Embodiment 1.

FIG. 3 is a cross-sectional view showing a configuration of the RC-IGBT and a state during operation of the FWD in Embodiment 2.

FIG. 4 is a view showing a state during a reverse recovery operation of the RC-IGBT in Embodiment 2.

FIG. 5 is a cross-sectional view showing a configuration of the RC-IGBT and a state during operation of the FWD in Embodiment 3.

FIG. 6 is a plan view of an RC-IGBT in Embodiment 4.

FIG. 7 is a cross-sectional view showing a configuration of an RC-IGBT and a state during operation of a FWD in a comparative example.

FIG. 8 is a view showing a state during a reverse recovery operation of the RC-IGBT in the comparative example.

### DETAILED DESCRIPTION OF EMBODIMENTS

Embodiments of the present disclosure will be described in detail below with reference to the attached drawings. In the present specification and attached drawings, electrons or holes in layers or areas marked with an “n” or “p” signify majority carriers. The “+” or “−” attached to the “n” or “p” respectively signify higher impurity concentrations and lower impurity concentrations than layers or areas without these marks. In the explanation of the embodiments below and the attached drawings, the same reference characters are attached to similar configurations and repetitive descriptions will be omitted. Furthermore, when representing Miller indices in the present specification, “−” signifies a bar attached to the index immediately thereafter, and attaching a “−” before the index represents a negative index.

In the respective embodiments below, n-type is a first conductivity type, and p-type is a second conductivity type.

### Embodiment 1

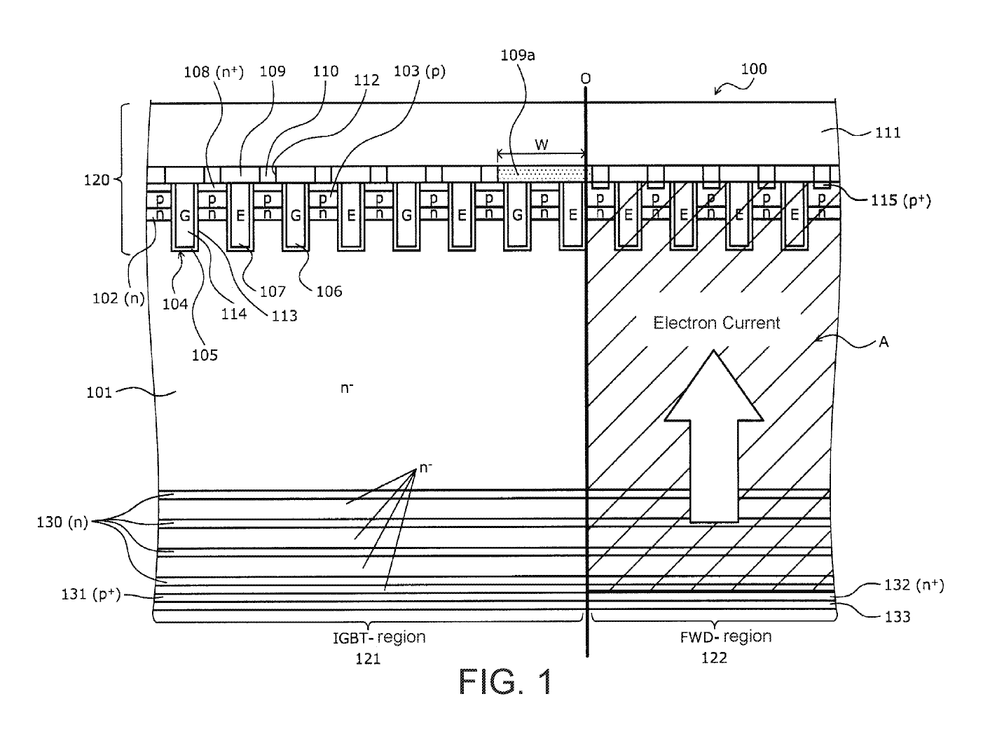

FIG. 1 is a cross-sectional view showing a configuration of an RC-IGBT and a state during operation of a FWD in Embodiment 1. In FIG. 1, the arrow shows electron current.

In the RC-IGBT, a trench-gate type MOS gate (an insulated gate made of metal-oxide film-semiconductor) structure 120 is provided in the front surface of an n⁻ semiconductor substrate, which serves as an n⁻ drift layer 101, in an IGBT region 121 that is a first device region where an insulated gate bipolar transistor is provided.

The MOS gate structure 120 includes a plurality of trench structures 104 formed in the front surface side of the n⁻ semiconductor substrate, n-type regions 102 and p-type regions 103 provided between adjacent trench structures 104, n⁺ emitter regions 108 formed on the p-type base regions 103, an interlayer insulating film 109 provided on the n⁺ emitter regions 108 and containing contact holes 112 therein, and an emitter electrode 111 that connects to the n⁺ emitter regions 108 via the contact holes 112. The contact holes 112 are filled with a contact plug 110 such as tungsten (W). The trench structure 104 includes a trench 113, an insulating film 105 provided on the inner side of the trench 113, and an electrode 114 provided on the inner side of the insulating film 105. The plurality of trench structures 104 include gate trench structures 106 in which the electrode 114 therein is based on a gate potential, and dummy trench structures 107 in which the electrode 114 therein is based on an emitter potential or is a floating potential. In the dummy trench structure 107, the electrode 114 is electrically isolated from the gate potential.

When viewed from the front surface side of the semiconductor device (semiconductor wafer) 100, the trench structures 104 (trenches 113) are arranged in a stripe pattern in a direction that extends in a direction (depth direction in FIG. 1) orthogonal to the width direction (horizontal direction in FIG. 1) in which the IGBT region (first device region) 121 and FWD region 122 (second device region) are arranged. The emitter electrode 111 is electrically connected to the n⁺ emitter regions 108 in the IGBT region 121.

The n-type regions 102 act as barriers for the minority carriers (holes) in the n⁻ drift layer 101 during turn ON of the IGBT and function to store the minority carriers in the n⁻ drift layer 101. The gate trench structures 106 and dummy trench structures 107 are formed in the IGBT region 121. The gate trench structures 106 and dummy trench structures 107 are alternately arranged, for example. The gate trench structure 106 is filled with a polycrystalline silicon electrode 114 via an insulating film 105, for example. The polycrystalline silicon is connected to a gate pad (not shown) to fix the potential to the gate potential.

The dummy trench structure 107 is also filled with a polycrystalline silicon electrode 114 via an insulating film 105, for example. The dummy trench structure 107, however, is fixed to the emitter potential. Accordingly, the dummy trench structure 107 does not function as the gate trench structure 106 (gate electrode). The dummy trench structure 107 need not have a fixed potential and may be a floating potential instead.

The emitter electrode 111, interlayer insulating film 109, contact plugs 110 (contact holes 112), trench structures 104, p-type base regions 103, n-type regions 102, n⁻ drift layer 101, n-type field stop layers 130, and collector electrode 133 are provided from the IGBT region 121 toward the FWD region 122. These may be provided with prescribed gaps therebetween in the width direction. However, it is not necessary to form all or even a portion of these with an equal prescribed gap therebetween, and furthermore, they are not necessarily provided with an equal prescribed gap therebetween. The prescribed gap may also be deviated at a boundary O portion. The n⁺ emitter regions 108 and p⁺ collector region 131 are formed across the IGBT region 121. P⁺ regions 115 and an n⁺ cathode region 132 are formed across the FWD region 122.

In the FWD region 122, each of the trench structures 104 is the dummy trench structure 107. The dummy trench structure 107 is fixed to the emitter potential. The p⁺ regions 115 and emitter electrode 111 are provided on the p-type base regions 103 and also function as the p-type anode regions and anode electrode of the FWD. By using Ai-Si as the electrode material of the emitter electrode 111, it is possible to form a favorable Ohmic contact with the p-type base regions 103 in the IGBT region 121. Furthermore, by using Ai-Si as the electrode material of the emitter electrode 111, it is also possible to form a favorable Ohmic contact with the p⁺ regions 115 (p-type anode regions) in the FWD region 122. Contact plugs 110 such as tungsten (W) are also filled into the contact holes 112 in the interlayer insulating film 109 in the FWD region 122.

In the configuration example of FIG. 1, a plurality of n-type field stop layers 130 are provided in the thickness direction in the rear surface side of the n⁻ semiconductor substrate. The p⁺ collector region 131 is also provided in the IGBT region 121 and the n⁺ cathode region 132 is provided in the FWD region 122 on the rear surface side of the n-type field stop layers 130. However, the n-type field stop layers 130 do not need to be provided, or any number of layers may be provided. In this example, the plurality of n-type field stop layers are formed by injecting protons a plurality of rounds, and these n-type field stop layers are caused to function as the equivalent of a single broad n-type field stop layer. However, the n-type field stop layers may also be formed deep inside the substrate by emitting n-type impurities such as phosphorous or arsenic from the grinding surface on the rear surface of the wafer and then performing annealing at a suitable temperature, or the n-type field stop layers may be formed with selenium or sulfur instead.

By providing the n-type field stop layers 130, it is possible to stop the depletion layer extending from the pn junctions between the p-type base regions 103 and n-type regions 102 during OFF and inhibit the depletion layer from reaching the p⁺ collector region 131, thus making it possible to reduce ON voltage. Furthermore, the n⁻ drift layer 101 can be made thinner. The collector electrode 133 also functions as a cathode electrode and contacts the p⁺ collector region 131 and n⁺ cathode region 132.

The interlayer insulating film 109 covers and insulates the trench structures 104 on the IGBT region 121 side or the FWD region 122 side of the boundary O between the IGBT region 121 and FWD region 122. In Embodiment 1, an interlayer insulating film 109a covering the contact region of the IGBT region 121 adjacent to the FWD region 122 is formed with a prescribed width W from the boundary O portion. In other words, the contact holes 112 (contact plugs 110) are not formed in this prescribed width W from the boundary O portion. The boundary O portion is the boundary between the p⁺ collector region 131 and n⁺ cathode region 132, for example.

The prescribed width W is equivalent to one cell or several cells (e.g., 5 μm), for example. If the prescribed width W is increased, the channel will decrease, and thus the prescribed width W is set as appropriate based on the channel. In the configuration example of FIG. 1, there is thus a region where the emitter contact is not formed due to the interlayer insulating film 109a, which has a width of at least two trench structures 104 (gate trench structure 106 and dummy trench structure 107) in the IGBT region 121 near the FWD region 122.

Specifically, during manufacturing of the semiconductor device, chemical vapor deposition (CVD), for example, is used to form the interlayer insulating film 109 on the front surface of the semiconductor substrate. Thereafter, when etching to form the contact holes 112, etching may be prevented across two trench structures (the gate trench structure 106 and dummy trench structure 107) by using a resist mask. This makes it possible to form the interlayer insulating film 109a portion of the prescribed width W via ordinary etching using a resist mask and without changing the manufacturing steps.

As described above, a configuration corresponding to the contact hole 112 (contact plug 110) is not formed in the IGBT region 121 of the prescribed width W adjacent to the FWD region 122. Due to this, there is no contact hole 112 (contact plug 110) present between the n⁺ emitter region 108/p-type base region 103 and emitter electrode 111, the n⁺ emitter region 108 and p-type base region 103 are insulated by the interlayer insulating film 109a, and no emitter contact is formed.

Furthermore, even if a voltage were to be applied to the gate trench structures 106 of the IGBT region 121, the interlayer insulating film 109a insulates the area within the prescribed width W. Accordingly, the interlayer insulating film 109a suppresses mobility of electrons and holes.

Due to this, electron current during FWD operation will no longer be drawn towards the IGBT region 121 side. An electron current region A at such time would be on the FWD region 122 side of the boundary O, which makes it possible to reduce the region having electron current drawn to the IGBT region 121 side. In this manner, it is possible to prevent deterioration of Vf during FWD operation due to the electron current no longer being drawn from the adjacent IGBT region during FWD operation.

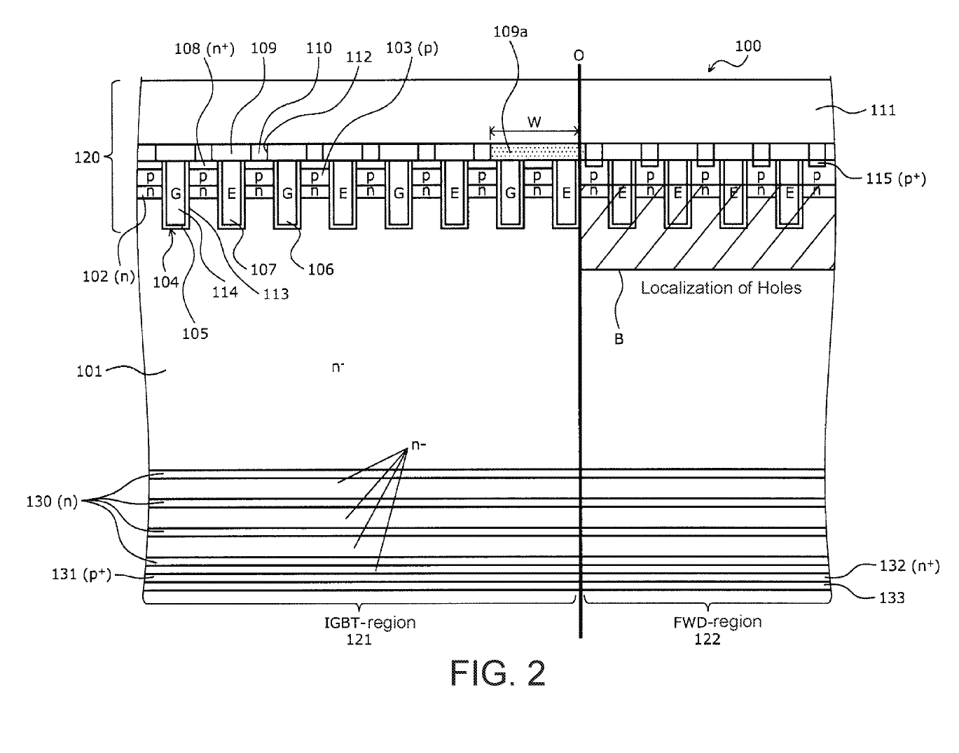

FIG. 2 is a view showing a state during a reverse recovery operation of the RC-IGBT in Embodiment 1. The RC-IGBT of Embodiment 1 makes it possible to prevent an increase in Irrm during reverse recovery operation of the RC-IGBT.

Mobility of electrons and holes is inhibited by the structure shown in FIGS. 1 and 2 in which the contact hole 112 (contact plug 110) is not formed, or namely the structure in which a portion of the IGBT region 121 adjacent to the FWD region 122 is covered and insulated by the interlayer insulating film 109a.

This prevents holes from being injected from the p-type base regions 103 or the like in the IGBT region 121 near the FWD region 122. Therefore, there will be no occurrence of a region B where carriers are susceptible to being present in the IGBT region 121 near the anode side. In other words, holes will be localized at the FWD region 122 side bordering the boundary O, which makes it possible to eliminate regions in the IGBT region 121 side where holes would localize. Accordingly, it is possible to prevent an increase in reverse recovery current (reverse recovery peak current) Irrm during reverse recovery operation of the FWD.

According to Embodiment 1 described above, the interlayer insulating film is formed in the IGBT region in a segment (portion) having a prescribed width from the boundary with the FWD region, and the contact holes 112 (contact plugs 110) are not formed in this segment of the IGBT region, thus making it possible to prevent electron current during conduction operation of the FWD from being drawn to the IGBT region, and thereby preventing deterioration of Vf. The interlayer insulating film of the prescribed width can be formed in a simple manner at the same time and in the same way as interlayer insulating films in the other regions; the interlayer insulating film of the prescribed width can be manufactured in a simple manner without requiring a special step or increasing the number of steps.

Furthermore, an increase in Irrm can also be prevented during reverse recovery operation of the FWD, making it possible to prevent degradation of the device characteristics of the RC-IGBT. Moreover, the above makes it possible to improve cell density and prevent characteristic degradation of Vf and Irrm in an RC-IGBT having trench structures. An interlayer insulating film (not shown) covering the contact region of the FWD region 122 adjacent to the IGBT region 121 may be formed with a prescribed width from the boundary O portion, or an interlayer insulating film covering the contact region on only one side from the boundary O portion may be formed.

The above example described the trench gate structures 106 and dummy trench structures 107 as being alternately arranged, but a plurality of the dummy trench structures 107 may be provided between the gate trench structures 106. In such a case, the ON voltage can be lowered by covering the area directly above the semiconductor regions (p-type base regions 103, for example) between the dummy trench structures 107 with the interlayer insulating film 109 without providing the contact holes 112. This segment covered by the interlayer insulating film directly above the semiconductor region between the dummy trench structures 107 may be set to the prescribed width W. Meanwhile, in the segment having the prescribed width W, it is even better for the interlayer insulating film 109a to cover and insulate at least the gate trench structure 106. Furthermore, in the segment having the prescribed width W, it is even better for the interlayer insulating film 109a to cover and insulate the gate trench structure 106 and dummy trench structure 107. This would make it possible to effectively prevent a deterioration of Vf during FWD operation and an increase in Irrm.

### Embodiment 2

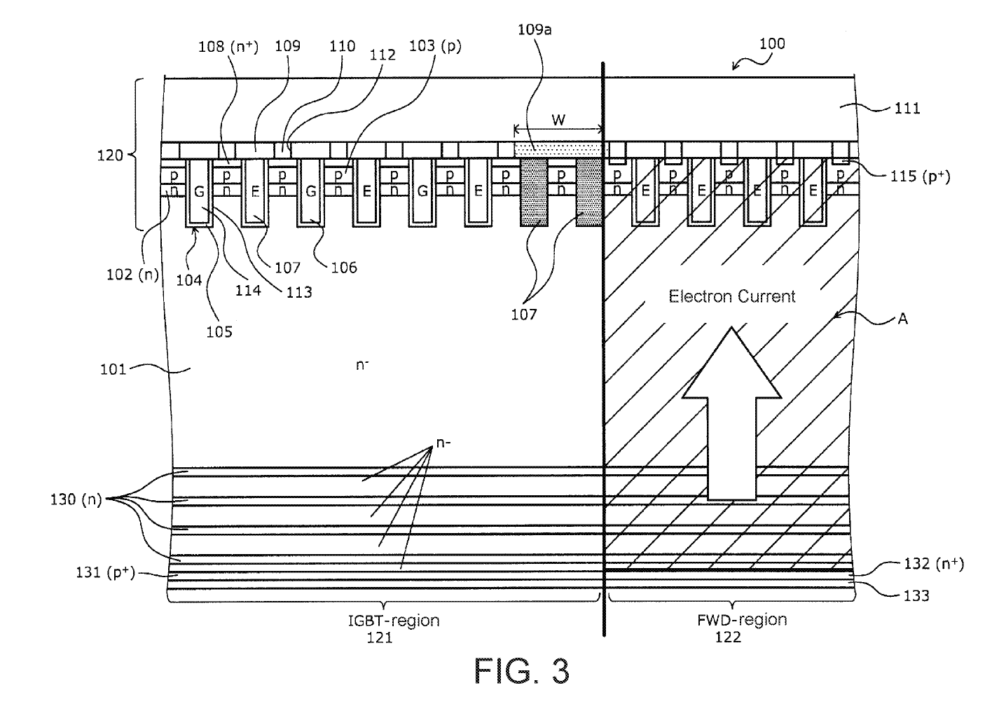

FIG. 3 is a cross-sectional view showing a configuration of the RC-IGBT and a state during operation of the FWD in Embodiment 2. Embodiment 2 is a modification example of the configuration described in Embodiment 1 (FIG. 1). As shown in FIG. 3, in Embodiment 2, the IGBT region 121 has the interlayer insulating film 109a at the prescribed width W from the boundary O with the FWD region 122, in a similar manner to Embodiment 1. In other words, the contact plugs 110 are not present between the n⁺ emitter regions 108 and the emitter electrode 111, and the n⁺ emitter regions 108 are insulated by the interlayer insulating film 109a.

In Embodiment 2, the electrode 114 of the trench structure 104 in the segment having the prescribed width W is not fixed to either the gate potential or the emitter potential but is instead a floating potential. Namely, the trench structure 104 in the segment having the prescribed width W is the dummy trench structure 107 with a floating potential.

The method of forming the dummy trench structure 107 with the floating potential includes filling an electrode 114 such as a polycrystalline silicon electrode into the trench 113 positioned directly below the interlayer insulating film 109a, for example. In addition, the draw-out part of the trench structure 104 is not connected to either but is instead covered by the interlayer insulating film 109a. At such time, the contact hole 112 is not formed in the interlayer insulating film 109a.

With this configuration, the trench structure 104 in the IGBT region 121 having the prescribed width W and adjacent to the FWD region 122 is not conductive with the emitter electrode but is instead in a floating state; thus, electron current (electron current region A) during FWD operation is not drawn toward the IGBT region 121 side. In this manner, it is possible to prevent deterioration of Vf during FWD operation due to the electron current no longer being drawn from the adjacent IGBT region during FWD operation. In the segment having the prescribed width W in which the interlayer insulating film 109a is provided, the gate trench structure 106 may be provided in addition to the dummy trench structure 107 with the floating potential.

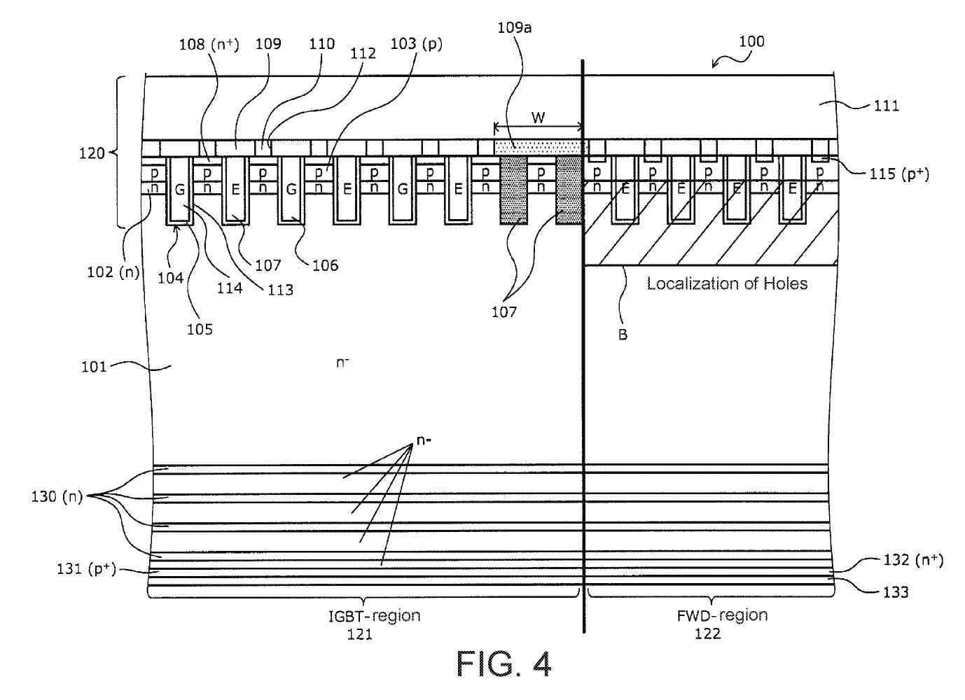

FIG. 4 is a view showing a state during a reverse recovery operation of the RC-IGBT in Embodiment 2. The RC-IGBT of Embodiment 2 makes it possible to prevent an increase in Irrm during reverse recovery operation of the RC-IGBT.

By setting a floating potential for the electrode in the trench structure 104 in the IGBT region 121 having the prescribed width W adjacent to the FWD region 122, holes are prevented from being injected from the p-type base regions 103 or the like in the IGBT region 121 near the FWD region 122. Therefore, there will be no occurrence of a region B where carriers are susceptible to being present near the anode side of the IGBT region 121. Accordingly, it is possible to prevent an increase in reverse recovery current (reverse recovery peak current) Irrm during reverse recovery operation of the FWD.

As described above, in Embodiment 2, the interlayer insulating film having the prescribed width from the boundary with the FWD region is formed in the IGBT region, and the electrode in the trench structure is set to floating, which prevents electron current during conduction operation of the IGBT region FWD from being drawn to the IGBT region, thereby making it possible to prevent deterioration of Vf. Furthermore, an increase in Irrm can also be prevented during reverse recovery operation of the FWD, making it possible to prevent degradation of the device characteristics of the RC-IGBT. Moreover, the above makes it possible to improve cell density and prevent characteristic degradation of Vf and Irrm in an RC-IGBT having trench structures. By setting the electrode in the trench structure to floating, it is also possible to lower the source-drain capacitance Cds.

The dummy trench structure 107 of the floating potential can be left as-is covered by the interlayer insulating film 109a without the draw out portion of the trench structure 104 being connected to anything. Further, the trench structures covered by the interlayer insulating film 109a may be dummy trench structures 107 filled with an insulating material, as shown in the shaded trenches 107 in FIG. 3.

### Embodiment 3

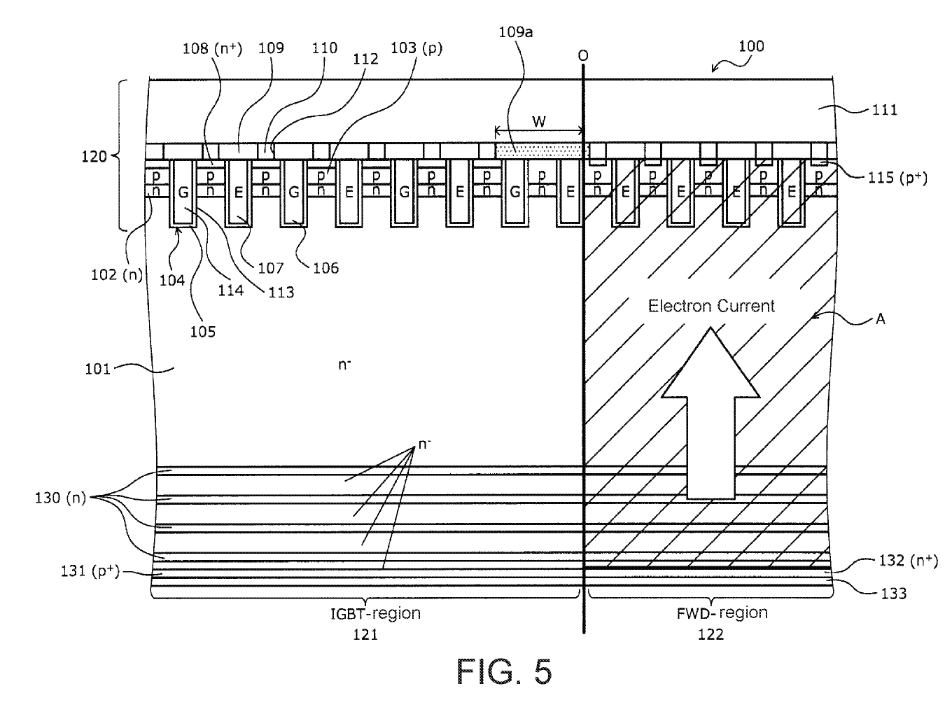

FIG. 5 is a cross-sectional view showing a configuration of the RC-IGBT and a state during operation of the FWD in Embodiment 3. Embodiment 3 differs from Embodiments 1 and 2 in that some of the n⁺ emitter regions 108 are not formed.

In a case in which the emitter contact is not formed in the portion of the IGBT region 121 adjacent to the FWD region 122 but instead the interlayer insulating film 109a covers the prescribed width W, which is described in Embodiments 1 and 2 above, the n⁺ emitter region 108 of the prescribed width W portion need not be formed. The n⁺ emitter regions 108 are formed as a device structure in the front surface during manufacturing, but at such time only the n⁺ emitter region 108 directly below the interlayer insulating film 109a is not formed. For example, during forming of the n⁺ emitter regions 108, it is permissible to use a resist mask so as not to form the n⁺ emitter region 108 directly below the interlayer insulating film 109a.

The present embodiment does not form the device structure in the portion covered by the interlayer insulating film 109a at the prescribed width W in the front surface side of the n⁻ semiconductor substrate, which serves as the n⁻ drift layer 101. Accordingly, in this example only the n⁺ emitter region 108 is not formed, but in a case in which a p⁺ contact region (not shown) contacting the emitter electrode 111 in a similar manner to the n⁺ emitter regions 108 is formed, it is not necessary to form this device structure either. In the portion covered by the interlayer insulating film 109a at the prescribed width W, it is also not necessary to form the n-type regions 102 or p-type base regions 103 constituting the MOS gate (insulated gate made of metal-oxide film-semiconductor) structure 120 sandwiched by the trench structures 104.

This would make it possible to effectively prevent a deterioration of Vf during FWD operation and an increase in Irrm.

### Embodiment 4

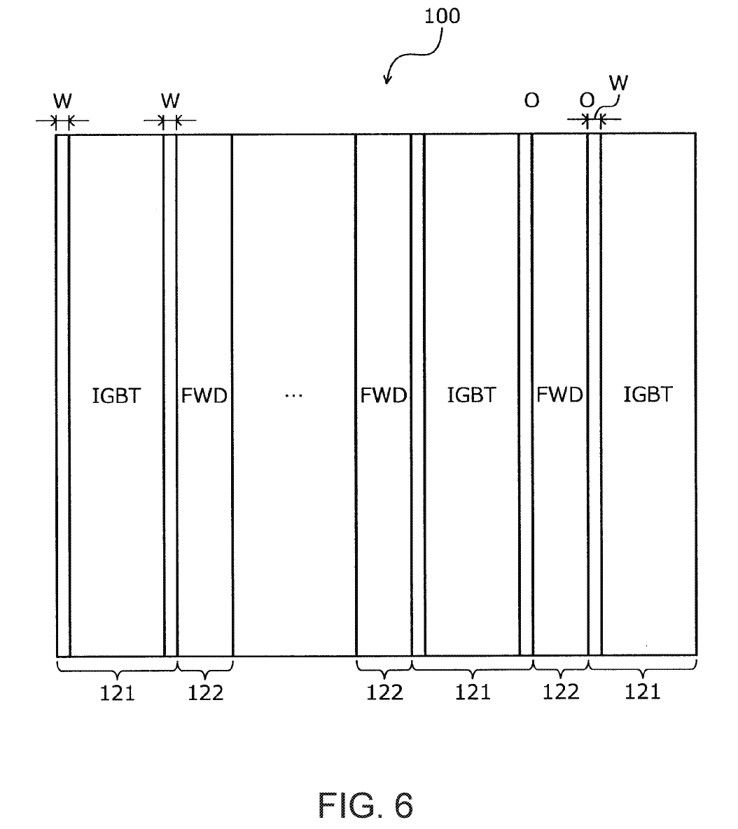

FIG. 6 is a plan view of an RC-IGBT in Embodiment 4. As shown in FIG. 6, the RC-IGBT semiconductor device 100 has IGBT regions 121 and FWD regions 122 each having prescribed widths and alternately arranged next to each other in the width direction.

The interlayer insulating film 109a described in Embodiments 1 to 3 above may be formed inside the IGBT regions 121 with a prescribed width from boundaries O with the FWD regions 122 adjacent to both ends in the width direction. This makes it possible to have a simple structure with similar effects to above in an RC-IGBT semiconductor device 100 having a plurality of IGBT regions 121 and FWD regions 122.

### Comparative Example

A configuration of an RC-IGBT of a comparative example will be described below using a configuration example of an active area in which the IGBT and FWD are embedded and integrated on the same semiconductor chip.

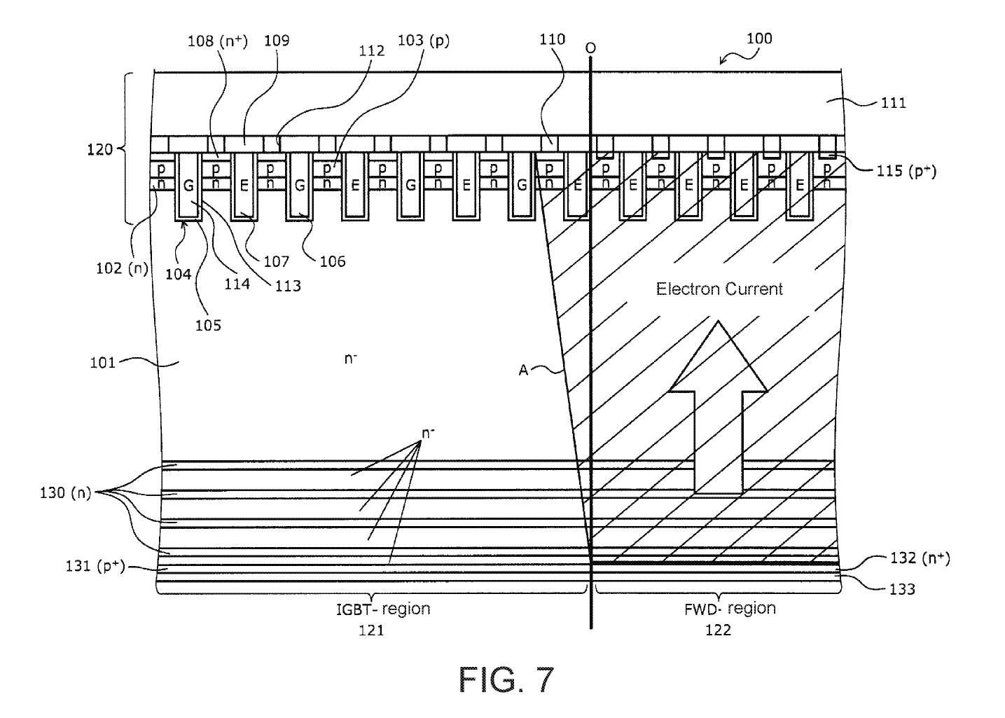

FIG. 7 is a cross-sectional view showing a configuration of an RC-IGBT and a state during operation of a FWD in the comparative example. As shown in FIG. 7, in the RC-IGBT of the comparative example, the IGBT region 121 and FWD region 122 are provided adjacent to each other with the boundary O therebetween. In the IGBT region 121, a trench-gate type MOS gate (insulated gate made of metal-oxide film-semiconductor) structure 120 is provided in the front surface of an n⁻ semiconductor substrate, which serves as an n⁻ drift layer 101.

The MOS gate structure 120 includes a plurality of trench structures 104, n-type regions 102, p-type base regions 103, n⁺ emitter regions 108, an interlayer insulating film 109 containing contact holes 112 therein, and an emitter electrode 111. Contact plugs 110 such as tungsten (W) are filled into the contact holes 112. The trench structure 104 includes a trench 113, an insulating film 105 provided on the inner side of the trench 113, and an electrode 114 provided on the inner side of the insulating film 105. The plurality of trench structures 104 include gate trench structures 106 in which the electrode 114 therein is based on a gate potential, and dummy trench structures 107 in which the electrode 114 therein is based on an emitter potential or is a floating potential.

The gate trench structures 106 and dummy trench structures 107 are formed in the IGBT region 121. The gate trench structures 106 and dummy trench structures 107 are alternately arranged, for example. The gate trench structure 106 is filled with a polycrystalline silicon electrode 114 via an insulating film 105, for example. The polycrystalline silicon is connected to a gate pad (not shown) to fix the potential to the gate potential. The dummy trench structure 107 is also filled with a polycrystalline silicon electrode 114 via an insulating film 105, for example. The dummy trench structure 107, however, is fixed to the emitter potential. Accordingly, the dummy trench structure 107 does not function as the gate trench structure 106 (gate electrode).

The emitter electrode 111, interlayer insulating film 109, contact plugs 110 (contact holes 112), trench structures 104, p-type base regions 103, n-type regions 102, n-drift layer 101, n-type field stop layers 130, and collector electrode 133 are provided from the IGBT region 121 toward the FWD region 122. The n⁺ emitter regions 108 and p⁺ collector region 131 are formed across the IGBT region 121. The p⁺ regions 115 and n⁺ cathode region 132 are formed across the FWD region 122.

In the FWD region 122, each of the trench structures 104 is the dummy trench structure 107 fixed to an emitter potential. The p⁺ regions 115 and emitter electrode 111 are provided on the p-type base regions 103 and also function as the p-type anode region and anode electrodes of the FWD.

In the configuration example of FIG. 7, a plurality of n-type field stop layers 130 are provided in the thickness direction in the rear surface side of the n⁻ semiconductor substrate. The p⁺ collector region 131 is also provided in the IGBT region 121 and the n⁺ cathode region 132 is provided in the FWD region 122 on the rear surface side of the n-type field stop layers 130. The collector electrode 133 also functions as a cathode electrode and contacts the p⁺ collector region 131 and n⁺ cathode region 132. FIG. 7 shows a region A where electron current flows, but the boundary of region A gradually widens from the cathode electrode portion of the FWD region and enters inside the IGBT region side on the front surface side.

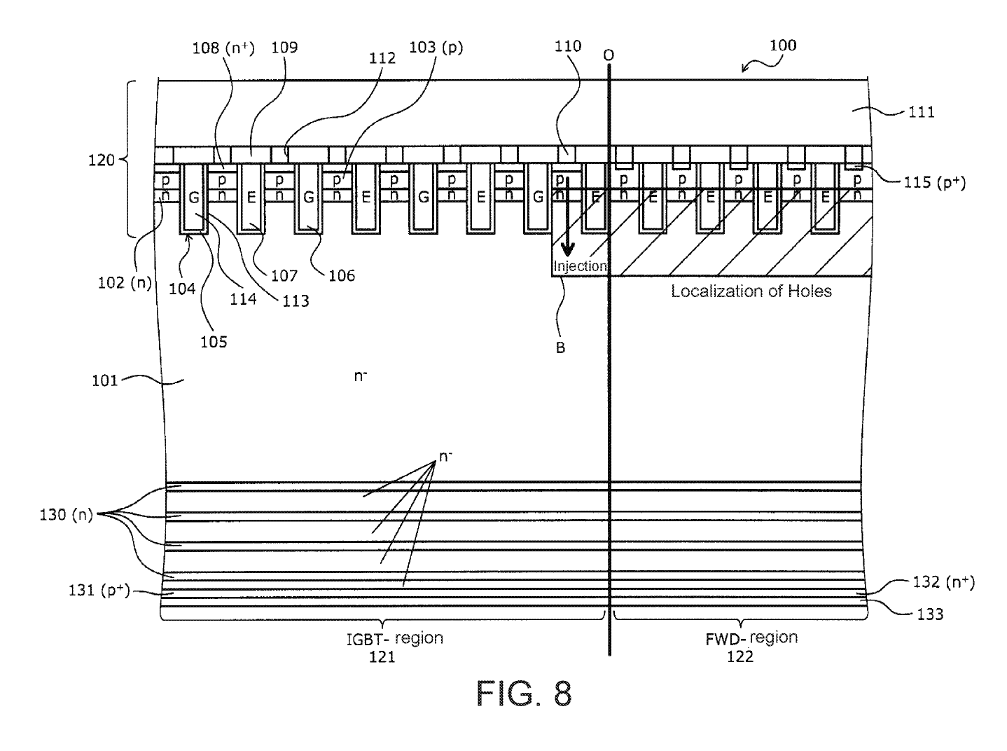

FIG. 8 is a view showing a state during a reverse recovery operation of the RC-IGBT in the comparative example. As shown in FIG. 8, during reverse recovery operation of the RC-IGBT, holes are injected from the emitter contact portion of the IGBT region 121 near the FWD region 122, and as a result, a region B that is susceptible to the presence of carriers is also generated in a region in the IGBT region 121 near the anode side, which causes an increase in reverse recovery current (reverse recovery peak current) Irrm during the reverse recovery operation. The deterioration of Vf during the conductive operation of the FWD and the increase in Irrm during the reverse recovery operation described above both cause degradation of device characteristics.

In the respective embodiments described above, an interlayer insulating film is formed in the IGBT region of the RC-IGBT in a segment having a prescribed width from the boundary with the FWD region, and an emitter contact is not formed in the segment. This makes it possible to prevent the electron current during conductive operation of the FWD from being drawn to the IGBT region and makes it possible to prevent deterioration of Vf. The interlayer insulating film having the prescribed width can be formed in a simple manner at the same time and in the same way as the interlayer insulating film in the other regions; the interlayer insulating film having the prescribed width can be manufactured in a simple manner without requiring a special step or increasing the number of steps.

Furthermore, an increase in Irrm can also be prevented during reverse recovery operation of the FWD, making it possible to prevent degradation of the device characteristics of the RC-IGBT. Moreover, the above makes it possible to improve cell density and prevent characteristic degradation of Vf and Irrm in an RC-IGBT having trench structures.

The present invention as described above is not limited to the aforementioned embodiments, and various modifications can be made without departing from the spirit of the present invention.

As described above, the semiconductor device of the present disclosure would be useful for a power semiconductor device such as a power device, a power semiconductor device used for industrial motor control or engine control, or the like.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device, comprising,
a semiconductor substrate of a first conductivity type serving as a drift layer, the semiconductor substrate having two defined regions of a first region where an insulated gate bipolar transistor is disposed and a second region where a diode is disposed,
wherein in the first region, the semiconductor device comprises:
a plurality of trench structures provided in a front surface side of the semiconductor substrate;
base regions of a second conductivity type disposed between the plurality of trench structures;
emitter regions of the first conductivity type respectively disposed on at least some of the base regions;
an interlayer insulating film covering the emitter regions and the plurality of trench structures; and
an emitter electrode on the interlayer insulating film, connected to at least some of the emitter regions, and
wherein the interlayer insulating film has contact holes therein connecting said at least some of the emitter regions to the emitter electrode, the interlayer insulating film not having said contact holes in a portion of the first region that is next to and abuts a boundary between the first region and the second region, and covering and insulating at least two of the trench structures that are adjacent to said boundary in said portion of the first region.

2. The semiconductor device according to claim 1, wherein the plurality of trench structures are also provided in the second region, and
wherein the interlayer insulating film and the emitter electrode extend from the first region towards the second region so as to be present in the second region.

3. The semiconductor device according to claim 2, wherein the interlayer insulating film further covers and insulates a portion of the second region that abuts the first region having a second prescribed length from the first region.

4. The semiconductor device according to claim 2, wherein the plurality of trench structures each have a trench, an insulating film disposed on an inner side of the trench, and an electrode disposed on an inner side of the insulating film.

5. The semiconductor device according to claim 3, wherein the plurality of trench structures each have a trench, an insulating film disposed on an inner side of the trench, and an electrode disposed on an inner side of the insulating film.

6. The semiconductor device according to claim 2,
wherein the plurality of trench structures in the first region comprise:
gate trench structures each having a gate electrode therein configured to receive a gate potential; and
dummy trench structures each having an electrode therein configured to receive an emitter potential or a floating potential.

7. The semiconductor device according to claim 6, wherein said at least two trench structures covered and insulated by the interlayer insulating film in said portion of said first region are the gate trench structures.

8. The semiconductor device according to claim 6, wherein said at least two trench structures covered and insulated by the interlayer insulating film in said portion of said first region are the gate trench structure and the dummy trench structure.

9. The semiconductor device according to claim 6, wherein said at least two trench structures covered and insulated by the interlayer insulating film in said portion of said first region are the dummy trench structures.

10. The semiconductor device according to claim 6, wherein the plurality of trench structures in the second region comprise dummy trench structures each having an electrode therein configured to receive said emitter potential or said floating potential.

11. The semiconductor device according to claim 2,
wherein the plurality of trench structures in the first region comprise:
gate trench structures each having a gate electrode therein configured to receive a gate potential;
first dummy trench structures each having an electrode therein configured to receive an emitter potential or a floating potential; and
second dummy trench structures filled with an insulating material, and
wherein said at least two trench structures covered and insulated by the interlayer insulating film in said portion of said first region are the second dummy trench structures.

12. The semiconductor device according to claim 1, wherein said emitter region is not formed between said at least two trench structures that are covered and insulated by the interlayer insulating film in said portion of said first region.

13. The semiconductor device according to claim 1, wherein the first region and the second region are both provided in a plurality, and the first regions and the second regions are alternately arranged next to each other on the semiconductor substrate in a plan view.
